(19) United States
(12) Patent Application Publication
(10) Pub. No.: US 2026/0323980 A1
(43) Pub. Date: Oct. 15, 2026

(54) SEMICONDUCTOR DEVICE

(71) Applicant: WAVETEK MICROELECTRONICS CORPORATION, Hsinchu County (TW)

(72) Inventors: Min-Li CHOU, Hsinchu County (TW); Yan-Ting CHUANG, Hsinchu County (TW); Chun-Liang HOU, Hsinchu County (TW); Barry Jia-Fu LIN, Hsinchu County (TW); Hsien-Chin CHIU, Hsinchu County (TW)

(21) Appl. No.: 19/208,609

(22) Filed: May 15, 2025

(30) Foreign Application Priority Data
Apr. 10, 2025 (TW) 114113647

(51) Int. Cl. H10D 30/47; H10D 62/85; H10W 44/20

(52) U.S. Cl. CPC H10D 30/475; H10D 62/8503; H10W 44/20; H10W 44/248

(57) ABSTRACT

Disclosed is a semiconductor device, which includes an epitaxial substrate, a gate structure, a source electrode and a drain electrode, which are disposed on the epitaxial substrate. The epitaxial substrate includes a semiconductor substrate, a buffer layer formed on the semiconductor substrate, a gallium nitride channel layer formed on the buffer layer, and a barrier layer formed on the gallium nitride channel layer. There is a two-dimensional electron gas (2DEG) formed in the gallium nitride channel layer near the barrier layer. The source electrode and the drain electrode are disposed on the opposite sides of the gate structure respectively. One of the source electrode and the drain electrode is connected to an antenna, the other one of the source electrode and the drain electrode is connected to a tuning element, and the gate structure is configured to control a connection between the tuning element and the antenna.

This application claims the priority benefit of Taiwan Patent Application Ser. No. 114113647, filed on Apr. 10, 2025, the full disclosure of which is incorporated herein by reference.

### TECHNICAL FIELD

The present disclosure relates to a semiconductor device, in particular to a semiconductor device used in an antenna tuner.

### Related Art

Antennas are essential components in mobile communication systems with multiple working frequency bands. An antenna tuner is disposed between an antenna and a radio frequency (RF) front end, and the antenna tuner can provide adjustable impedance tuning through tuning elements to perform an impedance matching between a transceiver and the antenna, and adjust the resonant frequency of the antenna, thereby improving the transmission efficiency and quality of the signal.

The antenna tuner includes a plurality of switch circuits connected in parallel and a tuning element connected in series to each switch circuit. Existing switch circuits typically use silicon-on-insulator (SOI) transistors with a low breakdown voltage, so that the existing switch circuit typically comprises at least twenty-five SOI transistors connected in series to achieve a breakdown voltage of 100 volts, which is suitable for antenna tuners in high-power environments (e.g., 34 dBm RF power in the 5th generation mobile communication technology (5G) systems). However, since at least twenty-five SOI transistors are connected in series to form a switch circuit, a capacitor is required to compensate for nonlinear changes caused by voltage changes, resulting in problems of a large form factor and poor linear control.

Therefore, how to provide a solution to the above-mentioned technical problems is a problem that those skilled in the art need to solve.

### SUMMARY

Embodiments of the present disclosure provide a semiconductor device. When applied to an antenna tuner, the semiconductor device can solve the problems of a large form factor and poor linear control of the existing antenna tuner since each switch circuit of the antenna tuner requires at least twenty-five SOI transistors to be connected in series to achieve the high breakdown voltage and requires a capacitor to compensate for nonlinear changes caused by voltage changes.

To solve the above technical problems, the present disclosure is implemented as follows.

The present disclosure provides a semiconductor device applied to an antenna tuner. The semiconductor device includes an epitaxial substrate, a gate structure, a source electrode and a drain electrode. The epitaxial substrate includes a semiconductor substrate, a buffer layer formed on the semiconductor substrate, a gallium nitride channel layer formed on the buffer layer, and a barrier layer formed on the gallium nitride channel layer. There is a two-dimensional electron gas formed in the gallium nitride channel layer near the barrier layer. The gate structure, source electrode and drain electrode are disposed on the epitaxial substrate, and the source electrode and the drain electrode are respectively arranged on opposite sides of the gate structure. One of the source electrode and the drain electrode is configured to connect an antenna, and the other one of the source electrode and the drain electrode is configured to connect a tuning element. The gate structure is configured to control a connection or a disconnection between the tuning element and the antenna.

In the embodiments of the present disclosure, the breakdown capability of the semiconductor device is increased through the material properties of the gallium nitride channel layer (i.e., a wide bandgap), so that when the semiconductor device is applied to an antenna tuner, the switching circuit of the antenna tuner only needs a single semiconductor device or a small number of semiconductor devices (less than 25) connected in series to meet the requirement of high breakdown voltage. In addition, since a small number of semiconductor devices are connected in series, it is not necessary to use a capacitor to compensate for the nonlinear changes caused by voltage changes. Therefore, the antenna tuner using the semiconductor device of the present disclosure has a smaller form factor and better linear control, and is suitable for high output power operating systems.

### BRIEF DESCRIPTION OF THE DRAWINGS

The accompanying drawings described herein are used to provide further understanding for the present disclosure, and constitute a part of the present disclosure. The exemplary embodiments of the present disclosure and their descriptions are used to explain the present disclosure, and do not constitute an improper limitation of the present disclosure. In the accompanying drawings:

FIG. 1 is a schematic diagram of an embodiment of a radio frequency circuit of an antenna tuner using an antenna tuning switch structure of the present disclosure;

FIG. 2 is a schematic diagram of a first embodiment of the antenna tuner of FIG. 1 connected to an antenna;

FIG. 3 is a schematic diagram of a second embodiment of the antenna tuner of FIG. 1 connected to an antenna;

FIG. 4 is a schematic diagram of a third embodiment of the antenna tuner of FIG. 1 connected to an antenna; and

FIG. 5 is a schematic diagram of a fourth embodiment of the antenna tuner of FIG. 1 connected to an antenna.

### DETAILED DESCRIPTION OF THE EMBODIMENTS

The embodiments of the present disclosure will be described below with reference to the drawings. Directional terminology mentioned in the following embodiments, such as up, down, left, right, front, back, etc., is used with reference to the orientation of the figure(s) being described. As such, the directional terminology is used for purposes of illustration and not for limitation of the present disclosure. In the figures, the same reference numerals represent the same or similar elements or process flows.

It must be understood that the words “including”, “comprising” and the like used in this specification are used to indicate the existence of specific technical features, values, method steps, work processes, elements and/or components. However, it does not exclude that more technical features, values, method steps, work processes, elements, components, or any combination thereof can be added.

It must be understood that when an element is described as being “connected” or “coupled” to another element, it may be directly connected or coupled to another element, and intermediate elements therebetween may be present. In contrast, when an element is described as “directly connected” or “directly coupled” to another element, there is no intervening element therebetween.

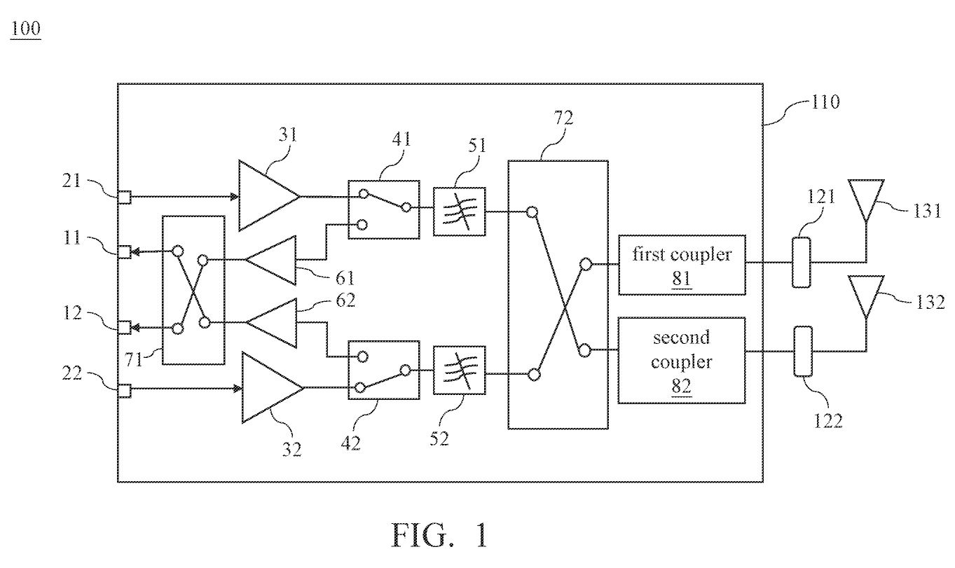

Please refer to FIG. 1, which is a schematic diagram of an embodiment of a radio frequency circuit of an antenna tuner using an antenna tuning switch structure of the present disclosure. As shown in FIG. 1, a radio frequency (RF) circuit 100 comprises a RF front end 110, an antenna tuner 121, an antenna tuner 122, an antenna 131, and an antenna 132. The RF front end 110 comprises a first signal receiving terminal 11, a first signal output terminal 21, a first power amplifier 31, a first single pole double throw (SPDT) switch 41, a first filter 51, a first low noise amplifier (LNA) 61, a first double pole double throw (DPDT) switch 71, a first coupler 81, a second signal receiving terminal 12, a second signal output terminal 22, a second power amplifier 32, a second SPDT switch 42, a second filter 52, a second LNA 62, a second DPDT switch 72 and a second coupler 82.

The antenna 131 and the antenna 132 may be a monopole antenna, an inverted F-shaped antenna (IFA), a loop antenna, a dipole antenna or a planar inverted-F antenna (PIFA), respectively. The first power amplifier 31 is configured to amplify a radio frequency signal with a first frequency band from the first signal output terminal 21, and the second power amplifier 32 is configured to amplify a radio frequency signal with a second frequency band from the second signal output terminal 22.

The first filter 51 is a bandpass filter configured to pass an RF signal in the first frequency band, and the second filter 52 is a bandpass filter configured to pass an RF signals in the second frequency band. The bandpass filter may be a filter configured to pass an RF signal (e.g., with less than 3 dB attenuation) within a frequency band. The first filter 51 and the second filter 52 may comprise an acoustic filter, an inductor-capacitor (LC) filter, a cavity filter, or a combination thereof. The acoustic filter comprises a surface acoustic wave (SAW) filter, a bulk acoustic wave (BAW) filter, and the like. The first frequency band may be a Long Term Evolution (LTE) frequency band, and the second frequency band may be a wireless local area network (WLAN) frequency band.

The first LNA 61 is configured to amplify the RF signal with the first frequency band that passes through the first filter 51 and output the amplified RF signal with the first frequency band. The second LNA 62 is configured to amplify the RF signal with the second frequency band that passes through the second filter 52 and output the amplified RF signal with the second frequency band. The first coupler 81 and the second coupler 82 may be, but are not limited to, directional couplers.

The antenna tuner 121 is connected to the antenna 131, and the antenna tuner 122 is connected to the antenna 132. The antenna 131 and the antenna 132 are configured to transmit and receive signals of different frequency bands. The antenna tuner 121 is configured to perform an impedance matching between the antenna 131 and the RF front end 110 and adjust the resonant frequency of the antenna 131. The antenna tuner 122 is configured to perform an impedance matching between the antenna 132 and the RF front end 110 and adjust the resonant frequency of the antenna 132.

After the first signal output terminal 21 receives the radio frequency signal with the first frequency band from the radio frequency transceiver (not shown), the radio frequency signal with the first frequency band is transmitted to the antenna 131 through the first power amplifier 31, the first SPDT switch 41, the first filter 51, the second DPDT switch 72, the first coupler 81 and the antenna tuner 121, so that the antenna 131 may convert the radio frequency signal with the first frequency band into an electromagnetic wave with the first frequency band and radiate the electromagnetic wave with the first frequency band. The antenna 131 may receive the electromagnetic wave with the first frequency band in the space. After the antenna 131 converts the electromagnetic wave with the first frequency band into the radio frequency signal with the first frequency band, the radio frequency signal with the first frequency band is transmitted to the radio frequency transceiver through the antenna tuner 121, the first coupler 81, the second DPDT switch 72, the first filter 51, the first SPDT switch 41, the first LNA 61, the first DPDT switch 71 and the first signal receiving terminal 11.

After the second signal output terminal 22 receives the RF signal with the second frequency band from the RF transceiver, the RF signal with the second frequency band is transmitted to the antenna 132 through the second power amplifier 32, the second SPDT switch 42, the second filter 52, the second DPDT switch 72, the second coupler 82 and the antenna tuner 122, so that the antenna 132 may convert the RF signal with the second frequency band into an electromagnetic wave with the second frequency band and radiate the electromagnetic wave with the second frequency band. The antenna 132 may receive the electromagnetic wave with the second frequency band in the space. After the antenna 132 converts the electromagnetic wave with the second frequency band into the RF signal with the second frequency band, the RF signal with the second frequency band is transmitted to the RF transceiver through the antenna tuner 122, the second coupler 82, the second DPDT switch 72, the second filter 52, the second SPDT switch 42, the second LNA 62, the first DPDT switch 71 and the second signal receiving terminal 12.

The antenna tuner 121, the antenna tuner 122, the first SPDT switch 41, the first DPDT switch 71, the second SPDT switch 42, and the second DPDT switch 72 may be controlled by the RF transceiver. The circuit architecture of the antenna tuner 121 and the circuit architecture of the antenna tuner 122 may be the same or different and may be adjusted and designed according to actual needs. The antenna tuner 121 and the antenna tuner 122 may be high-power antenna tuners, such as fourth generation of mobile phone mobile communication technology standards (4G) antenna tuners o 5G antenna tuners for smartphones, Wi-Fi antenna tuners for routers, and Internet of Things (IoT) RF front-end antenna tuners or transfer switches for wireless modules, but this embodiment is not intended to limit the present disclosure.

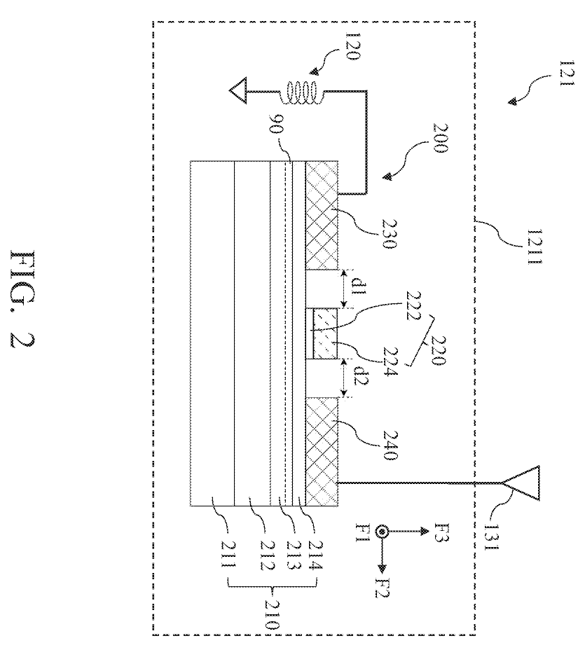

Please refer to FIGS. 1 and 2, wherein FIG. 2 is a schematic diagram of a first embodiment of the antenna tuner of FIG. 1 connected to an antenna. The switch circuit 1211 of the antenna tuner 121 may adopt a single semiconductor device 200 (i.e., the semiconductor device 200 is applied to the antenna tuner 121). The semiconductor device 200 comprises an epitaxial substrate 210, a gate structure 220, a source electrode 230, and a drain electrode 240. The epitaxial substrate 210 comprises a semiconductor substrate 211, a buffer layer 212 formed on the semiconductor substrate 211, a gallium nitride channel layer 213 formed on the buffer layer 212, and a barrier layer 214 formed on the gallium nitride channel layer 213. There is a two-dimensional electron gas 90 formed in the gallium nitride channel layer 213 near the barrier layer 214. The two-dimensional electron gas 90 refers to a phenomenon that an electron gas can move freely in a two-dimensional direction but is restricted in a third dimension, which can significantly improve the carrier/electron migration speed of the semiconductor device 200. The two-dimensional electron gas 90 forms a conductive channel of the semiconductor device 200. The gate structure 220, the source electrode 230 and the drain electrode 240 are disposed on the epitaxial substrate 210. The source electrode 230 and the drain electrode 240 are respectively arranged on opposite sides of the gate structure 220. One of the source electrode 230 and the drain electrode 240 is configured to connect the antenna 131, and the other one of the source electrode 230 and the drain electrode 240 is configured to connect the tuning element 120. The gate structure 220 is configured to control a connection or a disconnection between the tuning element 120 and the antenna 131.

It should be noted that, in order to facilitate explanation and help understand the structure of the semiconductor device 200 of the present disclosure, the drawings of the present disclosure show spatial directions such as a first direction F1, a second direction F2 and a third direction F3. The first direction F1 and the second direction F2 are perpendicular to each other and parallel to the surface of the epitaxial substrate 210, and the third direction F3 is perpendicular to the surface of the epitaxial substrate 210.

In this embodiment, the source electrode 230 may be connected to the tuning element 120, the tuning element 120 may be an inductor, and the drain electrode 240 may be connected to the antenna 131. The buffer layer 212, the gallium nitride channel layer 213 and the barrier layer 214 may form a gallium nitride heterostructure. The buffer layer 212, the gallium nitride channel layer 213 and the barrier layer 214 may all be formed by an epitaxial growth process, such as a metal-organic chemical vapor deposition (MOCVD) process, a hydride vapor phase epitaxy (HVPE) process, a molecular beam epitaxy (MBE) process, a combination of the above and other similar methods. The semiconductor device 200 may be a gallium nitride high electron mobility transistor (GaN HEMT). The RF front end may be configured to control the gate structure 220, and further control the connection or the disconnection between the tuning element 120 and the antenna 131, but this embodiment is not intended to limit the present disclosure.

The breakdown capability of the semiconductor device 200 is increased through the material properties of the gallium nitride channel layer 213 (i.e., a wide bandgap), so that when the semiconductor device 200 is applied to the antenna tuner 121, the semiconductor device 200 can meet the requirement of high breakdown voltage and has high power handling performance, and does not need to use capacitors to compensate for nonlinear changes caused by voltage changes. Therefore, the antenna tuner 121 using the semiconductor device 200 has a smaller form factor and better linear control, and is suitable for high output power operating systems.

It should be noted that the switch circuit 1211 of the antenna tuner 121 may also adopt M semiconductor devices 200 connected in series, where M is a positive integer greater than or equal to 2.

In one embodiment, when the switching circuit 1211 of the antenna tuner 121 comprises M semiconductor devices 200 connected in series, the drain electrode 240 of the first semiconductor device 200 of the semiconductor devices 200 connected in series may be connected to the tuning element 120, and the source electrode 230 of the Mth semiconductor device 200 of the semiconductor devices 200 connected in series may be connected to the antenna 131. If M is a positive integer greater than or equal to 3, the drain electrode 240 of the Kth semiconductor device 200 (1<K<M) of the semiconductor devices 200 connected in series may be connected to the source electrode 230 of the semiconductor device 200 adjacent to one side of the Kth semiconductor device 200, and the source electrode 230 of the Kth semiconductor device 200 of the semiconductor devices 200 connected in series may be connected to the drain electrode 240 of the semiconductor device 200 adjacent to the other side of the Kth semiconductor device 200. In other words, the drain electrode 240 of each of the semiconductor devices 200 connected in series may be directly or indirectly connected to the tuning element 120, and the source electrode 230 of each of the semiconductor devices 200 connected in series may be directly or indirectly connected to the antenna 131.

In another embodiment, when the switching circuit 1211 of the antenna tuner 121 comprises M semiconductor devices 200 connected in series, the source electrode 230 of the first semiconductor device 200 of the semiconductor devices 200 connected in series may be connected to the tuning element 120, and the drain electrode 240 of the Mth semiconductor device 200 of the semiconductor devices 200 connected in series may be connected to the antenna 131. If M is a positive integer greater than or equal to 3, the source electrode 230 of the Kth semiconductor device 200 (1<K<M) of the semiconductor devices 200 connected in series may be connected to the drain electrode 240 of the semiconductor device 200 adjacent to one side of the Kth semiconductor device 200, and the drain electrode 240 of the Kth semiconductor device 200 of the semiconductor devices 200 connected in series may be connected to the source electrode 230 of the semiconductor device 200 adjacent to the other side of the Kth semiconductor device 200. In other words, the source electrode 230 of each of the semiconductor devices 200 connected in series may be directly or indirectly connected to the tuning element 120, and the drain electrode 240 of each of the semiconductor devices 200 connected in series may be directly or indirectly connected to the antenna 131.

In one embodiment, the semiconductor substrate 211 may be, but is not limited to, a substrate with a resistivity greater than 500 ohm-cm. Since the gallium nitride channel layer 213 is formed on the semiconductor substrate 211 with high resistivity, the isolation may be improved, thereby avoiding the loss of radio frequency signals. In one example, a material of the semiconductor substrate 211 may be Si (111), and may be a silicon substrate grown using a float zone growing method (i.e., the floating zone silicon grown by vertical zone melting/refinement of a high purity polycrystalline rod). In another example, the material of the semiconductor substrate 211 may be silicon carbide.

In one embodiment, the buffer layer 212 may comprise carbon-doped gallium nitride (C-GaN), iron-doped gallium nitride (Fe-GaN), a multiple-stacked layer of carbon-doped gallium nitride and iron-doped gallium nitride, or an aluminum gallium nitride back barrier layer. The thickness of the buffer layer 212 may be, but is not limited to, 500 nanometers to 1500 nanometers. The buffer layer 212 may be used as a stress buffer layer to release stress formed in a semiconductor layer above the semiconductor substrate 211 (e.g., the gallium nitride channel layer 213) and reduce leakage of radio frequency signals through the semiconductor substrate 211. When the buffer layer 212 comprises the aluminum gallium nitride back barrier layer, the aluminum gallium nitride back barrier layer can prevent current collapse due to the surface polarization effect. By disposing the aluminum gallium nitride back barrier layer on the lower surface of the gallium nitride channel layer 213 and disposing the barrier layer 214 on the upper surface of the gallium nitride channel layer 213, the gallium nitride channel layer 213 has polarity, so that potential wells are generated in the gallium nitride channel layer 213 near the aluminum gallium nitride back barrier layer and the barrier layer 214, respectively, and a conductive channel is formed, so as to improve the stability and reliability of the semiconductor device 200. When the buffer layer 212 comprises carbon-doped gallium nitride and/or iron-doped gallium nitride, the presence of p-type dopants can help increase the breakdown voltage of the semiconductor device 200. When the buffer layer 212 comprises the multiple-stacked layer of carbon-doped gallium nitride and iron-doped gallium nitride, the resistance value can be increased, thereby preventing leakage current.

In one embodiment, the thickness of the gallium nitride channel layer 213 may be, but is not limited to, 50 nanometers to 1000 nanometers. Since the polarization charges between the barrier layer 214 and the gallium nitride channel layer 213 are positive polarization charges, a potential dip is formed at the interface between the barrier layer 214 and the gallium nitride channel layer 213, and free carriers are affected by the polarization field distribution and are gathered at the potential dip, thereby forming the two-dimensional electron gas 90 in the gallium nitride channel layer 213 near the barrier layer 214.

In one embodiment, a material of the barrier layer 214 may be, but is not limited to, aluminum gallium nitride (AlxGaN), and a percentage of aluminum in the aluminum gallium nitride may be, but is not limited to, 15% to 35%. In one embodiment, the thickness of the barrier layer 214 may be, but is not limited to, 5 nanometers to 40 nanometers. The barrier layer 214 is configured to increase the polarization effect to induce the two-dimensional electron gas 90 in the gallium nitride channel layer 213. When the percentage of aluminum in the aluminum gallium nitride is higher or the thickness of the barrier layer 214 is larger, the barrier layer 214 has a greater polarization effect, but generates greater stress. Therefore, after considering the balance between stress generation and polarization effect, when the material of the barrier layer 214 is aluminum gallium nitride (AlxGaN), the percentage of aluminum in the aluminum gallium nitride can be controlled to be 15% to 35%, and the thickness of the barrier layer 214 can be controlled to be 5 nanometers to 40 nanometers. In addition, when the buffer layer 212 comprises an aluminum gallium nitride back barrier layer and the material of the barrier layer is aluminum gallium nitride, epitaxial consistency and electrical uniformity can be ensured.

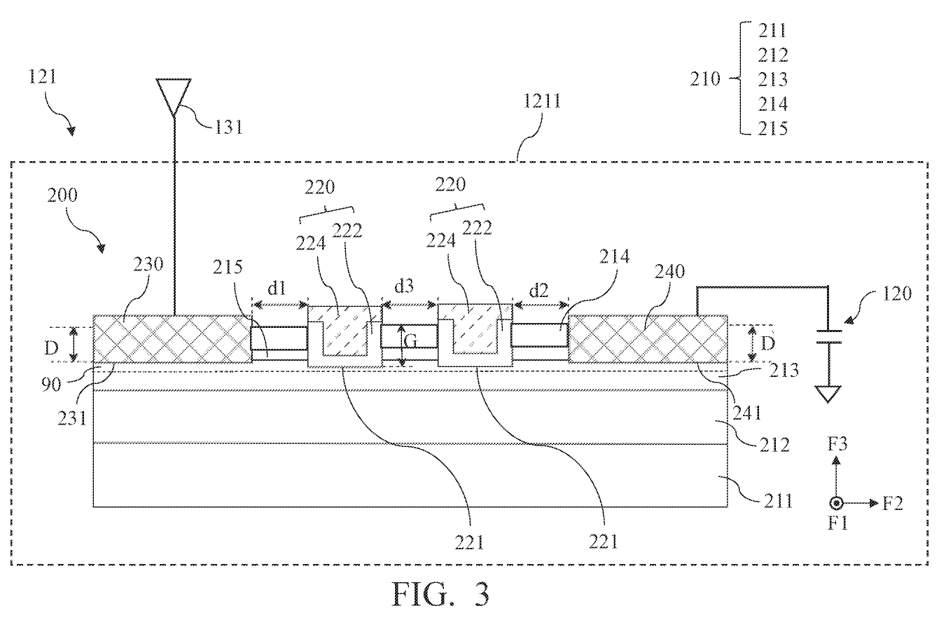

In one embodiment, the epitaxial substrate 210 may further comprise a spacer layer 215, and the spacer layer 215 is disposed between the barrier layer 214 and the gallium nitride channel layer 213 (as shown in FIG. 3, which is a schematic diagram of a second embodiment of the antenna tuner of FIG. 1 connected to an antenna), wherein a material of the spacer layer 215 may be, but is not limited to, aluminum nitride, and the thickness of the spacer layer 215 may be, but is not limited to, less than 5 nanometers. The spacer layer 215 is configured to generate quantum confinement to improve the mobility and density of the two-dimensional electron gas 90. In addition, in FIG. 3, the source electrode 230 may be connected to the antenna 131, and the drain electrode 240 may be connected to the tuning element 120, which may be a capacitor.

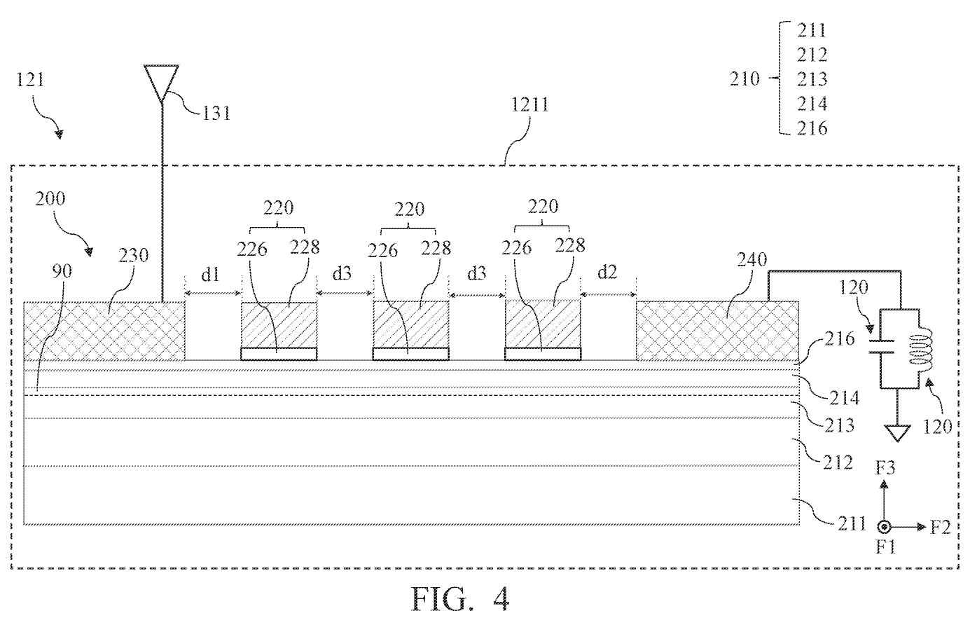

In one embodiment, the epitaxial substrate 210 may further comprise a cap layer 216, and the cap layer 216 is disposed on the barrier layer 214 (as shown in FIG. 4, which is a schematic diagram of a third embodiment of the antenna tuner of FIG. 1 connected to an antenna), wherein a material of the cap layer 216 may be, but is not limited to, gallium nitride, the thickness of the cap layer 216 may be, but is not limited to, less than 5 nanometers, and the cap layer 216 is configured to prevent aluminum in the barrier layer 214 from being oxidized. In addition, in FIG. 4, the source electrode 230 may be connected to the antenna 131, and the drain electrode 240 may be connected to two tuning elements 120 connected in parallel, and the two tuning elements 120 may be a capacitor and an inductor.

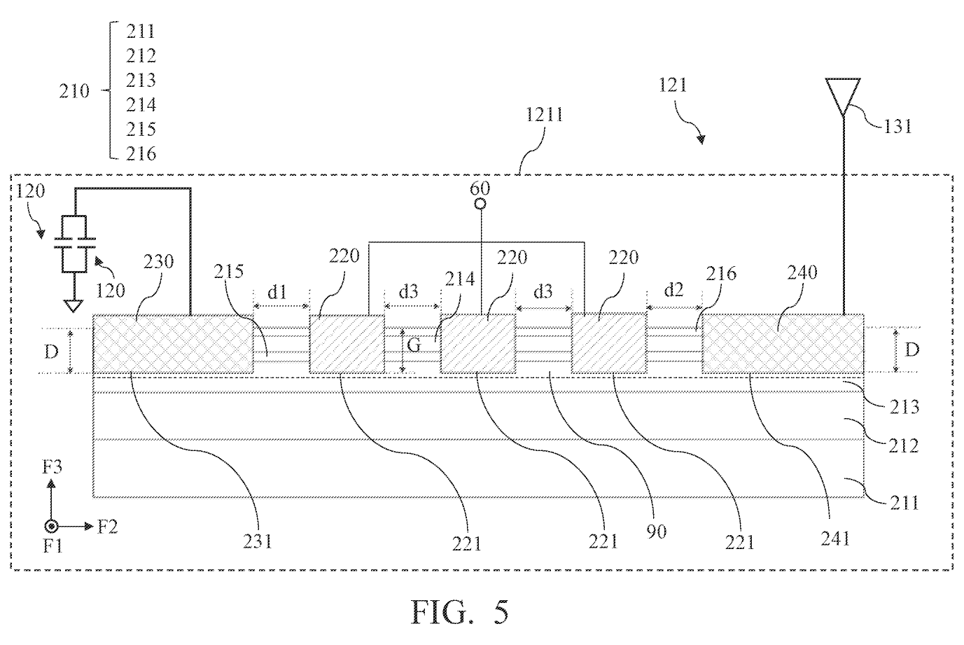

In one embodiment, the epitaxial substrate 210 may further comprise a spacer layer 215 and a cap layer 216, the spacer layer 215 is disposed between the barrier layer 214 and the gallium nitride channel layer 213, and the cap layer 216 is disposed on the barrier layer 214 (as shown in FIG. 5, FIG. 5 is a schematic diagram of a fourth embodiment of the antenna tuner of FIG. 1 connected to an antenna). In addition, in FIG. 5, the source electrode 230 may be connected to two tuning elements 120 connected in parallel, the two tuning elements 120 may be two capacitors, and the drain electrode 240 may be connected to the antenna 131.

In one embodiment, when the epitaxial substrate 210 comprises the semiconductor substrate 211, the buffer layer 212, the gallium nitride channel layer 213 and the barrier layer 214 stacked in sequence, the gate structure 220, the source electrode 230 and the drain electrode 240 directly contact the barrier layer 214 (as shown in FIG. 2).

In another embodiment, when the epitaxial substrate 210 comprises the semiconductor substrate 211, the buffer layer 212, the gallium nitride channel layer 213 and the barrier layer 214 stacked in sequence, the gate structure 220, the source electrode 230 and the drain electrode 240 can not only directly contact the barrier layer 214, but also extend into the epitaxial substrate 210. In other words, a gate recess 221, a source recess 231 and a drain recess 241 may be formed in the epitaxial substrate 210 first, and then the gate structure 220, the source electrode 230 and the drain electrode 240 may be formed in the gate recess 221, the source recess 231 and the drain recess 241. Among them, the gate structure 220 extends into the epitaxial substrate 210 (i.e., an opposite direction of the third direction F3) by a first distance G (i.e., the depth of the gate groove 221), and the first distance G may be less than or equal to 50 nanometers; and the source electrode 230 and the drain electrode 240 extends into the epitaxial substrate 210 respectively by a second distance D (i.e., the depth of the source groove 231 and the depth of the drain groove 241), and the second distance D may be less than or equal to 50 nanometers (as shown in FIG. 3). The source electrode 230 and the drain electrode 240 may selectively contact the two-dimensional electron gas 90 according to the second distance D. When the source electrode 230 and the drain electrode 240 directly contact the two-dimensional electron gas 90, the output current of the semiconductor device 200 may be increased. Since the source electrode 230 and the drain electrode 240 extend into the epitaxial substrate 210 respectively, the source electrode 230 and the drain electrode 240 have a larger contact area with the epitaxial substrate 210 respectively. The larger contact area may result in the semiconductor device 200 having a lower contact resistance, thereby resulting in a better performance of the semiconductor device 200 during the operation of the semiconductor device 200.

In one embodiment, the source electrode 230 and the drain electrode 240 may form ohmic contacts with the epitaxial substrate 210 respectively. The source electrode 230 and the drain electrode 240 may respectively comprise a conductive material or regrowth N-type gallium nitride (Regrowth N type-GaN), wherein the conductive material may comprise titanium (Ti), aluminum (Al), nickel (Ni), silver (Ag), gold (Au), platinum (Pt), chromium (Cr), copper (Cu), iridium (Ir), titanium nitride (TiN) and tungsten (W), compounds thereof, composite layers thereof or alloys thereof, but are not limited thereto; and the regrowth N-type gallium nitride may be, but is not limited to, silicon-gallium nitride (Si-GaN). In addition, the source electrode 230 and the drain electrode 240 may also be stacked layers that make ohmic contact with the epitaxial substrate 210, such as Ti/Al, Ti/Al/Ti/TiN, Ti/Al/Ti/Au or Ti/Al/Ni/Au, but not limited thereto.

In one embodiment, a distance d1 between the gate structure 220 and the source electrode 230 and a distance d2 between the gate structure 220 and the drain electrode 240 may be greater than or equal to 0.5 micrometers and less than or equal to 4 micrometers. In addition, the distance d1 between the gate structure 220 and the source electrode 230 and the distance d2 between the gate structure 220 and the drain electrode 240 may be the same or different.

In one embodiment, the number of the gate structures 220 is N, where N is a positive integer less than or equal to 6, and the source electrode 230 and the drain electrode 240 are respectively disposed on opposite sides of the N gate structures 220 (as shown in FIGS. 2 to 5). The RF front end can simultaneously control the N gate structures 220 (as shown in FIG. 5) through a single control terminal 60. The breakdown voltage (e.g., 50 volts to 400 volts) of the semiconductor device 200 can be increased by disposing a plurality of gate structures 220.

In one embodiment, a distance d3 between any two adjacent gate structures 220 may be greater than or equal to 0.5 micrometers and less than or equal to 4 micrometers.

In one embodiment, the gate structure 220 may be a metal-insulator-semiconductor (MIS) structure (as shown in FIGS. 2 and 3), wherein the MIS structure comprises a dielectric layer 222 in contact with the epitaxial substrate 210 and a gate electrode 224 disposed on the dielectric layer 222. The gate electrode 224 may comprise titanium, aluminum, nickel, gold, platinum, chromium, copper, iridium, titanium nitride, compounds thereof, composite layers thereof, or alloys thereof, and the dielectric layer 222 may comprise silicon nitride (SiNx), silicon oxide (SiOx), hafnium oxide (HfOx), or aluminum oxide (AlOx), but this embodiment is not intended to limit the present disclosure. By designing the gate structure 220 as a MIS structure, the gate leakage current of the semiconductor device 200 may be reduced and the breakdown capability of the semiconductor device 200 may be improved. The dielectric layer 222 may be formed by an atomic layer deposition (ALD) process. The ALD deposition technology is suitable for the deposition of the dielectric layer 222 due to good uniformity, thickness control, low deposition temperature (heat treatment budget), and plasma-free deposition (which can avoid plasma-induced damage to the underlying epitaxial layer).

In FIG. 2, since the epitaxial substrate 210 comprises the semiconductor substrate 211, the buffer layer 212, the gallium nitride channel layer 213 and the barrier layer 214 stacked in sequence, and the gate structure 220 directly contacts the barrier layer 214, the dielectric layer 222 of the gate structure 220 directly contacts the barrier layer 214, and the gate electrode 224 of the gate structure 220 is disposed on the dielectric layer 222.

In FIG. 3, since the gate structure 220 extends into the epitaxial substrate 210, the dielectric layer 222 of the gate structure 220 not only contacts the barrier layer 214 but also selectively contacts the gallium nitride channel layer 213 and the spacer layer 215 according to the first distance G extending from the gate structure 220 into the epitaxial substrate 210. The gate electrode 224 of the gate structure 220 is disposed on the dielectric layer 222.

In another embodiment, the gate structure 220 may comprise a gallium nitride layer 226 in contact with the epitaxial substrate 210 and a gate electrode 228 disposed on the gallium nitride layer 226 (as shown in FIG. 4), and a Schottky contact may be formed between the gate electrode 228 and the gallium nitride layer 226. The gate electrode 228 may comprise titanium, aluminum, nickel, gold, platinum, chromium, copper, iridium, titanium nitride or a compound thereof. The gate electrode 228 is in contact with the gallium nitride layer 226, and a Schottky barrier is formed at the contact surface (i.e., the so-called heterojunction), which may improve the breakdown capability and anti-noise capability of the semiconductor device 200.

In FIG. 4, since the epitaxial substrate 210 comprises the semiconductor substrate 211, the buffer layer 212, the gallium nitride channel layer 213, the barrier layer 214 and the cap layer 216 stacked in sequence, and the gate structure 220 directly contacts the cap layer 216, the gallium nitride layer 226 of the gate structure 220 directly contacts the cap layer 216, and the gate electrode 228 of the gate structure 220 is disposed on the gallium nitride layer 226.

In another embodiment, the gate structure 220 is a P-type gallium nitride gate (as shown in FIG. 5), wherein the P-type gallium nitride gate comprises carbon-doped gallium nitride or magnesium-doped gallium nitride. In addition, the P-type gallium nitride gate is configured to deplete the charge carriers generated in the underlying gallium nitride channel layer 213, so that the semiconductor device 200 is switched to be in a normally-off state. In addition, the P-type gallium nitride gate may be formed by an epitaxial growth process, such as a metal-organic chemical vapor deposition process, a molecular beam epitaxy process or a hydride vapor phase epitaxy process, and a photolithography process is used to define the pattern of the P-type gallium nitride gate.

In yet another embodiment, the gate structure 220 is a fluorine-doped gallium nitride gate.

In summary, the breakdown capability of the semiconductor device is increased through the material properties of the gallium nitride channel layer (i.e., a wide bandgap), so that when the semiconductor device is applied to an antenna tuner, the switching circuit of the antenna tuner only needs a single semiconductor device or a small number of semiconductor devices (less than 25) connected in series to meet the requirement of high breakdown voltage. In addition, since a small number of semiconductor devices are connected in series, there is no need to use a capacitor to compensate for the nonlinear changes caused by voltage changes. Therefore, the antenna tuner using the semiconductor device of the present disclosure has a smaller form factor and better linear control, and is suitable for high output power operating systems. Besides, the gallium nitride channel layer is formed on the semiconductor substrate with high resistivity (i.e., the resistivity greater than 500 ohm-cm), which may improve isolation and thus avoid RF signal loss. Furthermore, the breakdown voltage of the semiconductor device may be increased by disposing a plurality of gate structures. Moreover, by designing the gate structure as a MIS structure, the gate leakage current may be reduced, and the breakdown capability of the semiconductor device may be improved.

While the present disclosure is disclosed in the foregoing embodiments, it should be noted that these descriptions are not intended to limit the present disclosure. On the contrary, the present disclosure covers modifications and equivalent arrangements obvious to those skilled in the art. Therefore, the scope of the claims must be interpreted in the broadest manner to comprise all obvious modifications and equivalent arrangements.

What is claimed is:

1. A semiconductor device applied to an antenna tuner, the semiconductor device comprising:
an epitaxial substrate comprising a semiconductor substrate, a buffer layer formed on the semiconductor substrate, a gallium nitride channel layer formed on the buffer layer, and a barrier layer formed on the gallium nitride channel layer, wherein there is a two-dimensional electron gas (2DEG) formed in the gallium nitride channel layer near the barrier layer;
a gate structure disposed on the epitaxial substrate; and
a source electrode and a drain electrode respectively arranged on opposite sides of the gate structure and on the epitaxial substrate, wherein one of the source electrode and the drain electrode is configured to connect an antenna, and the other one of the source electrode and the drain electrode is configured to connect a tuning element, and the gate structure is configured to control a connection or a disconnection between the tuning element and the antenna.

2. The semiconductor device of claim 1, wherein the gate structure is a metal-insulator-semiconductor (MIS) structure, and the metal-insulator-semiconductor structure comprises a dielectric layer in contact with the epitaxial substrate and a gate electrode disposed on the dielectric layer.

3. The semiconductor device of claim 2, wherein the gate electrode comprises titanium, aluminum, nickel, gold, platinum, chromium, copper, iridium, titanium nitride, compounds thereof, composite layers thereof or alloys thereof, and a material of the dielectric layer is selected from the group consisting of silicon nitride (SiNx), silicon oxide (SiOx), hafnium oxide (HfOx), aluminum oxide (AlOx), and combinations thereof.

4. The semiconductor device of claim 1, wherein the gate structure comprises a gallium nitride layer in contact with the epitaxial substrate and a gate electrode disposed on the gallium nitride layer, and a Schottky contact is formed between the gate electrode and the gallium nitride layer.

5. The semiconductor device of claim 4, wherein the gate electrode comprises titanium, aluminum, nickel, gold, platinum, chromium, copper, iridium, titanium nitride or compounds thereof.

6. The semiconductor device of claim 1, wherein the gate structure is a P-type gallium nitride gate.

7. The semiconductor device of claim 6, wherein the P-type gallium nitride gate comprises carbon-doped gallium nitride or magnesium-doped gallium nitride.

8. The semiconductor device of claim 1, wherein the gate structure is a fluorine-doped gallium nitride gate.

9. The semiconductor device of claim 1, wherein the gate structure extends into the epitaxial substrate by a first distance, and the first distance is less than or equal to 50 nanometers.

10. The semiconductor device of claim 1, wherein the number of the gate structures is N, N is a positive integer less than or equal to 6, and the source electrode and the drain electrode are respectively arranged on opposite sides of the N gate structures.

11. The semiconductor device of claim 10, wherein a distance between any two adjacent gate structures is greater than or equal to 0.5 micrometers and less than or equal to 4 micrometers.

12. The semiconductor device of claim 1, wherein the source electrode and the drain electrode form ohmic contacts with the epitaxial substrate respectively.

13. The semiconductor device of claim 1, wherein the source electrode and the drain electrode extend into the epitaxial substrate respectively by a second distance, and the second distance is less than or equal to 50 nanometers.

14. The semiconductor device of claim 1, wherein the epitaxial substrate further comprises a spacer layer disposed between the barrier layer and the gallium nitride channel layer.

15. The semiconductor device of claim 1, wherein the epitaxial substrate further comprises a cap layer disposed on the barrier layer.

16. The semiconductor device of claim 1, wherein the semiconductor substrate is a substrate with a resistivity greater than 500 ohm-cm.

17. The semiconductor device of claim 16, wherein a material of the semiconductor substrate is Si (111) or silicon carbide.

18. The semiconductor device of claim 1, wherein the buffer layer comprises carbon-doped gallium nitride (C-GaN), iron-doped gallium nitride (Fe-GaN), a multiple-stacked layer of carbon-doped gallium nitride and iron-doped gallium nitride, or an aluminum gallium nitride back barrier layer.

19. The semiconductor device of claim 1, wherein a distance between the gate structure and the source electrode and a distance between the gate structure and the drain electrode are greater than or equal to 0.5 micrometers and less than or equal to 4 micrometers.

20. The semiconductor device of claim 1, wherein a material of the barrier layer is aluminum gallium nitride (AlxGaN), and a percentage of aluminum in the aluminum gallium nitride is 15% to 35%.
